(19) United States
(12) Patent Application Publication
(10) Pub. No.: US 2025/0031520 A1
(43) Pub. Date: Jan. 23, 2025

(54) DISPLAY DEVICE AND A METHOD FOR MANUFACTURING THE SAME

(71) Applicant: SAMSUNG DISPLAY CO., LTD., YONGIN-SI (KR)

(72) Inventor: Chun Gi YOU, Yongin-si (KR)

(21) Appl. No.: 18/732,807

(22) Filed: Jun. 4, 2024

(30) Foreign Application Priority Data
Jul. 18, 2023 (KR) 10-2023-0093174

(51) Int. Cl. H10K 59/121; H10K 59/12

(52) U.S. Cl. CPC H10K 59/1213; H10K 59/1201

(57) ABSTRACT

A display device and a method for manufacturing the same are disclosed. The display device includes: a display panel, wherein the display panel includes: a semiconductor wafer substrate; a complementary metal oxide semiconductor (CMOS) layer disposed on a first side of the semiconductor wafer substrate and including a plurality of display driving circuits that are driven independently of each other; a transistor layer disposed on a second side of the semiconductor wafer substrate and including a plurality of pixel driving circuits connected to the plurality of display driving circuits through a contact hole in the semiconductor wafer substrate; a light emitting element layer disposed on the second side of the semiconductor wafer substrate and including a light emitting element driven by the plurality of pixel driving circuits; and an encapsulation layer disposed on the second side of the semiconductor wafer substrate.

### CROSS-REFERENCE TO RELATED APPLICATION

This application claims priority under 35 U.S.C. 119 to Korean Patent Application No. 10-2023-0093174 filed on Jul. 18, 2023 in the Korean Intellectual Property Office, the disclosure of which is incorporated by reference herein in its entirety.

### 1. TECHNICAL FIELD

The present disclosure relates to a display device and a method for manufacturing the same.

### 2. DESCRIPTION OF THE RELATED ART

A wearable device, designed either as glasses or a helmet, is currently in development. This device is designed to project images at a distance close to the user's eyes. Examples of the wearable device include a head mounted display (HMD) device or augmented reality (AR) glass. Such a wearable device provides a user with an AR screen or a virtual reality (VR) screen.

The wearable device, such as the HMD device or the AR glass, requires a display with a specification of at least 2000 pixels per inch (PPI). This high resolution allows users to engage the device for long periods of time without experiencing discomfort or dizziness. In response to this requirement, the technology of organic light emitting diode on silicon (OLEDoS) is emerging. OLEDoS is a small organic light emitting display device with high resolution. OLEDoS is characterized by placing organic light emitting diodes (OLEDs) on a semiconductor wafer substrate on which a complementary metal oxide semiconductor (CMOS) is already disposed.

### SUMMARY

Embodiments of the present disclosure provide a display device capable of increasing the production yield of a display panel that has light emitting elements disposed on a semiconductor wafer substrate and that can be easily repaired. Embodiments of the present disclosure also provide a method for manufacturing the same.

According to an embodiment of the present disclosure, there is provided a display device including: a display panel, wherein the display panel includes: a semiconductor wafer substrate; a complementary metal oxide semiconductor (CMOS) layer disposed on a first side of the semiconductor wafer substrate and including a plurality of display driving circuits that are driven independently of each other; a transistor layer disposed on a second side of the semiconductor wafer substrate and including a plurality of pixel driving circuits connected to the plurality of display driving circuits through a contact hole in the semiconductor wafer substrate; a light emitting element layer disposed on the second side of the semiconductor wafer substrate and including a light emitting element driven by the plurality of pixel driving circuits; and an encapsulation layer disposed on the second side of the semiconductor wafer substrate.

The display panel includes a display area in which a plurality of pixels including the light emitting element are disposed, and a non-display area, and the plurality of display driving circuits overlap the plurality of pixels in the display area.

The plurality of display driving circuits are disposed at intervals in the CMOS layer.

The plurality of display driving circuits include the same circuits.

The plurality of display driving circuits include: a first display driving circuit disposed to correspond to a first area of the display area and including a first circuit for driving the plurality of pixel driving circuits; and a second display driving circuit disposed to correspond to a second area of the display area and including a second circuit for driving the plurality of pixel driving circuits, and the first circuit and the second circuit are the same.

The plurality of display driving circuits further include: a third display driving circuit disposed to correspond to a third area of the display area and including a third circuit for driving the plurality of pixel driving circuits; and a fourth display driving circuit disposed to correspond to a fourth area of the display area and including a fourth circuit for driving the plurality of pixel driving circuits, and the first, second, third and fourth circuits are the same.

The contact hole includes: a plurality of first contact holes connecting the first display driving circuit and the plurality of pixel driving circuits; a plurality of second contact holes connecting the second display driving circuit and the plurality of pixel driving circuits; a plurality of third contact holes connecting the third display driving circuit and the plurality of pixel driving circuits; and a plurality of fourth contact holes connecting the fourth display driving circuit and the plurality of pixel driving circuits.

Each of the plurality of pixel driving circuits includes an oxide-based thin film transistor.

The display panel further includes: a color filter layer disposed on the second side of the semiconductor wafer substrate and including a color filter; and a light control layer disposed on the second side of the semiconductor wafer substrate and including a refractive film.

The display panel further includes: a first cover window disposed on the first side of the semiconductor wafer substrate; and a second cover window disposed on the second side of the semiconductor wafer substrate.

According to an embodiment of the present disclosure, there is provided a method for manufacturing a display device, the method including: preparing a semiconductor wafer substrate; forming a CMOS layer including a plurality of display driving circuits that are driven independently of each other on a front surface of the semiconductor wafer substrate; attaching a first cover window to the CMOS layer; performing a chemical mechanical polishing pad (CMP) process step of polishing a rear surface of the semiconductor wafer substrate to expose contact holes connected to the plurality of display driving circuits; forming a transistor layer including a plurality of pixel driving circuits connected to the plurality of display driving circuits through the contact holes on the rear surface of the semiconductor wafer substrate; forming a light emitting element layer including a light emitting element driven by the plurality of pixel driving circuits on the transistor layer; and forming an encapsulation layer on the light emitting element layer.

A display panel included in the display device includes a display area in which a plurality of pixels including the light emitting element are disposed, and a non-display area, and the plurality of display driving circuits overlap the plurality of pixels in the display area.

The plurality of display driving circuits are disposed at intervals in the CMOS layer.

The plurality of display driving circuits include the same circuits.

The plurality of display driving circuits include: a first display driving circuit disposed to correspond to a first area of the display area and including a first circuit for driving the plurality of pixel driving circuits; and a second display driving circuit disposed to correspond to a second area of the display area and including a second circuit for driving the plurality of pixel driving circuits, and the first circuit and the second circuit are the same.

The plurality of display driving circuits further include: a third display driving circuit disposed to correspond to a third area of the display area and including a third circuit for driving the plurality of pixel driving circuits; and a fourth display driving circuit disposed to correspond to a fourth area of the display area and including a fourth circuit for driving the plurality of pixel driving circuits, and the first, second, third and fourth circuits are the same.

The contact hole includes: a plurality of first contact holes connecting the first display driving circuit and the plurality of pixel driving circuits; a plurality of second contact holes connecting the second display driving circuit and the plurality of pixel driving circuits; a plurality of third contact holes connecting the third display driving circuit and the plurality of pixel driving circuits; and a plurality of fourth contact holes connecting the fourth display driving circuit and the plurality of pixel driving circuits.

Each of the plurality of pixel driving circuits includes an oxide-based thin film transistor.

The method further includes: forming a color filter layer including a color filter on the encapsulation layer; and forming a light control layer including a refractive film on the color filter layer.

The method further includes attaching a second cover window to the light control layer.

According to the display device and the method for manufacturing the same according to the embodiments, the production yield of the display panel may be increased and the repair thereof may be simplified, thereby reducing the manufacturing cost of the display panel.

### BRIEF DESCRIPTION OF THE DRAWINGS

The above and other features of the present disclosure will become more apparent by describing in detail embodiments thereof with reference to the attached drawings, in which:

FIG. 1 is a perspective view illustrating a display device according to an embodiment;

FIG. 2 is a plan view illustrating a front surface of a display panel according to an embodiment;

FIG. 3 is a plan view illustrating a rear surface of the display panel according to an embodiment;

FIG. 4 is a configuration block diagram of the display device according to an embodiment;

FIG. 5A is a view illustrating a semiconductor wafer for manufacturing a display panel according to a comparative example;

FIG. 5B is a view illustrating a semiconductor wafer for manufacturing a display panel according to an embodiment;

FIG. 6 is a block diagram illustrating a connection between a display panel and any one of a plurality of display driving circuits according to an embodiment;

FIG. 7 is a circuit diagram of a pixel of the display device according to an embodiment;

FIG. 8 is a view illustrating a driving timing of a pixel driving circuit illustrated in FIG. 7;

FIG. 9 is a cross-sectional view of a portion of a display area of a display panel according to an embodiment;

FIG. 10 is a flowchart illustrating at least a portion of a process of manufacturing a display device according to an embodiment;

FIG. 11 is a view illustrating a step of preparing a semiconductor wafer;

FIG. 12 is a view illustrating a step of forming a complementary metal oxide semiconductor (CMOS) layer;

FIG. 13 is a view illustrating a step of attaching a first cover window;

FIG. 14 is a view illustrating a step of a chemical mechanical polishing pad (CMP) process;

FIG. 15 is a view illustrating a step of forming a transistor layer;

FIG. 16 is a view illustrating steps of forming a light emitting element layer and an encapsulation layer;

FIG. 17 is a view illustrating a virtual reality device including the display device according to an embodiment; and

FIGS. 18 and 19 are views illustrating a head mounted display device to which the display device according to an embodiment is applied.

### DETAILED DESCRIPTION OF THE EMBODIMENTS

The present disclosure will now be described more fully hereinafter with reference to the accompanying drawings, in which embodiments of the disclosure are shown. This disclosure may, however, be embodied in different forms and should not be construed as limited to the embodiments set forth herein.

It will be understood that when a layer is referred to as being “on” another layer or substrate, it can be directly on the other layer or substrate, or intervening layers may also be present. The same reference numbers may indicate the same components throughout the specification.

It will be understood that, although the terms “first,” “second,” etc. may be used herein to describe various elements, these elements should not be limited by these terms. These terms are merely used to distinguish one element from another element. For instance, a first element discussed below could be termed a second element. Similarly, the second element could also be termed the first element.

Features of each of various embodiments of the present disclosure may be partially or entirely combined with each other and may technically variously interwork with each other. In addition, respective embodiments may be implemented independently of each other or may be implemented together in association with each other.

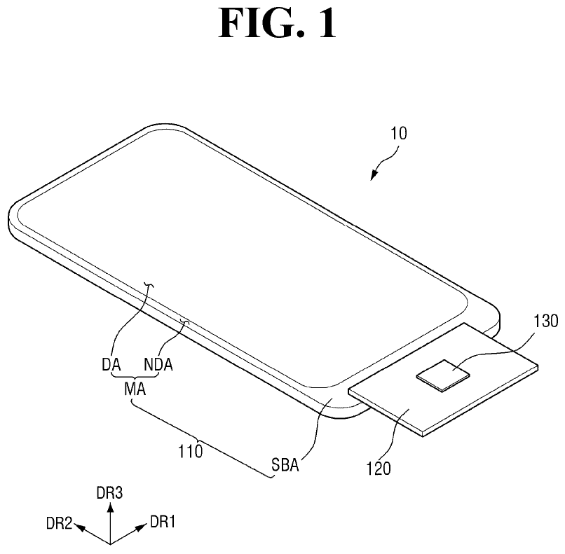

FIG. 1 is a perspective view illustrating a display device 10 according to an embodiment.

Referring to FIG. 1, the display device 10 may be applied to portable electronic devices such as a mobile phone, a smartphone, a tablet personal computer (PC), a mobile communication terminal, an electronic notebook, an electronic book, a portable multimedia player (PMP), a navigation device, and an ultra mobile PC (UMPC). For example, the display device 10 may be applied to a display unit of a television, a laptop computer, a monitor, a billboard, or the Internet of Things (IOT) device. As another example, the display device 10 may be applied to a wearable device such as a smart watch, a watch phone, a glasses-type display, and a head mounted display (HMD).

The display device 10 may be formed in a planar shape similar to a quadrangle. For example, the display device 10 may have a planar shape similar to a quadrangle having a short side in a horizontal direction DR1 and a long side in a vertical direction DR2. In FIG. 1, DR3 indicates a normal direction perpendicular to a plane formed by the horizontal direction DR1 and the vertical direction DR2. A corner where the short side and the long side meet may be formed to be rounded to have a predetermined curvature or formed at a right angle. The planar shape of the display device 10 is not limited to the quadrangle, and may be formed similarly to other polygons, circles, or ovals.

The display device 10 includes a display panel 110, a circuit board 120, and a power supply unit 130.

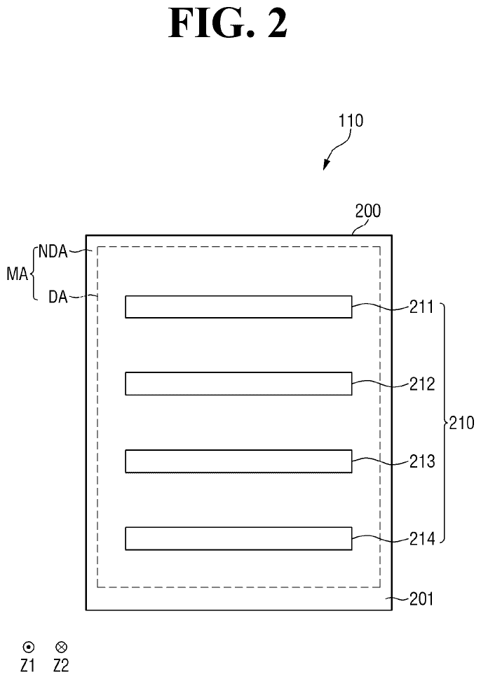

The display panel 110 uses a semiconductor wafer substrate 200 (see FIG. 2) as a base substrate. The display panel 110 may include a main area MA and a sub-area SBA. Herein, the semiconductor wafer substrate 200 may be referred to as a “substrate”.

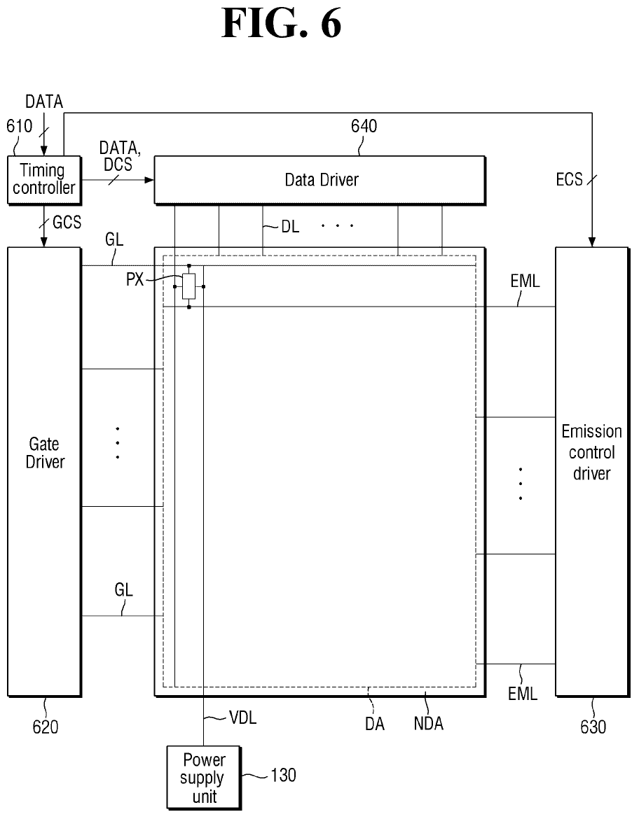

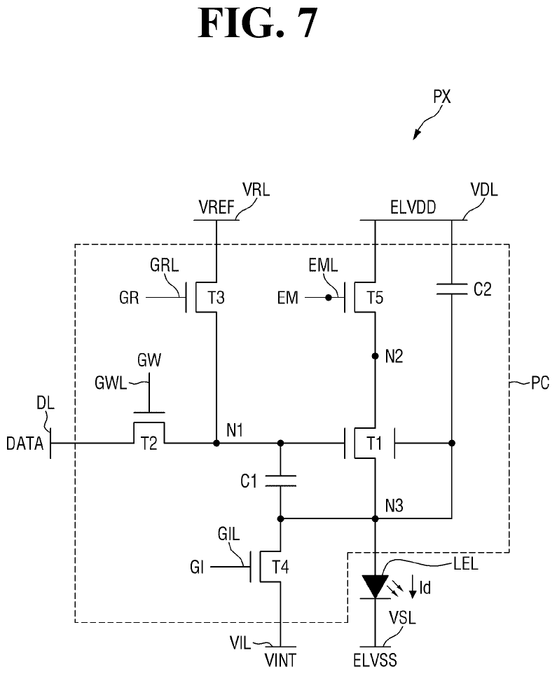

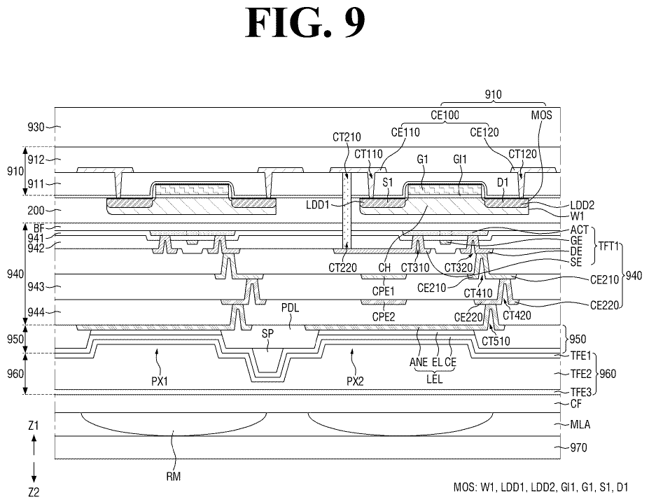

The main area MA may include a display area DA including pixels (PX in FIG. 6) for displaying an image, and a non-display area NDA disposed around the display area DA. The non-display area NDA may refer to an area other than the display area DA. The display area DA may emit light from a plurality of light emitting areas or a plurality of opening areas. For example, the display panel 110 may include a pixel driving circuit (PC in FIG. 7) including switching elements, a pixel defining film (PDL in FIG. 9) defining a light emitting area or an opening area, and a light emitting element (LEL in FIG. 9) that is a self-light emitting element (LEL).

The light emitting element LEL may include at least one of an organic light emitting diode (organic LED, OLED) including an organic light emitting layer, a quantum dot LED including a quantum dot light emitting layer, an inorganic LED including an inorganic semiconductor, and a micro LED, but is not limited thereto.

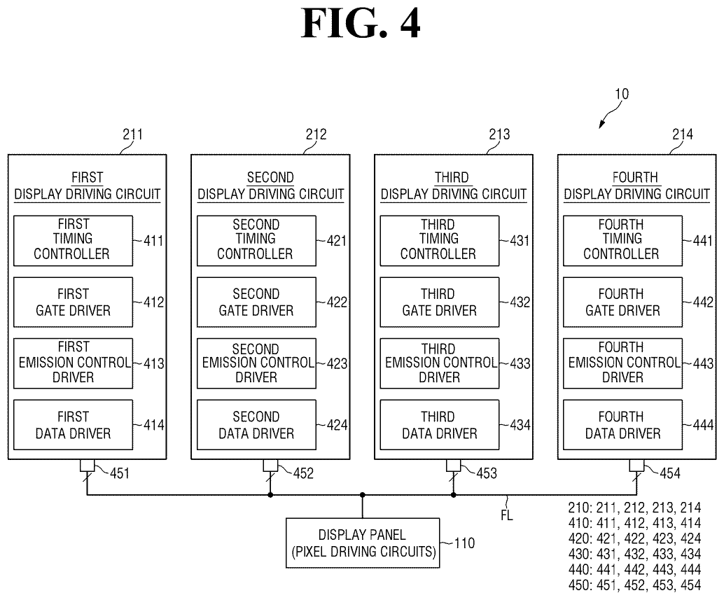

The non-display area NDA may be an area outside the display area DA. The non-display area NDA may be an edge area of the main area MA of the display panel 110. The non-display area NDA may include fan-out lines (FL in FIG. 4) extending from lines (e.g., gate lines, data lines, and emission control lines) of the display area DA. The non-display area NDA may further include a display pad portion connecting the fan-out lines FL and a plurality of display driving circuits 210 disposed on a front surface 201 of the semiconductor wafer substrate 200. For example, the display pad portion disposed in the non-display area NDA may be electrically connected to the plurality of display driving circuits 210 disposed on the front surface 201 of the semiconductor wafer substrate 200 through contact holes (450 in FIG. 4 and CT210 and CT220 in FIG. 9) penetrating through the semiconductor wafer substrate 200.

The sub-area SBA may extend from one side of the main area MA. The sub-area SBA may include a main pad portion connected to the circuit board 120. Optionally, the sub-area SBA may be omitted, and the main pad portion may be disposed in the non-display area NDA.

The circuit board 120 may be attached onto the main pad portion of the display panel 110 using an anisotropic conductive film (ACF). Lead lines of the circuit board 120 may be electrically connected to the main pad portion of the display panel 110. The circuit board 120 may be a flexible printed circuit board, a printed circuit board, or a flexible film such as a chip on film.

The power supply unit 130 may be disposed on the circuit board 120, and may supply a power voltage to the display driving circuits 210 and the display panel 110. The power supply unit 130 may generate a driving voltage and supply the driving voltage to a driving voltage line VDL (see FIG. 6). In addition, the power supply unit 130 may generate a common voltage and supply the common voltage to a common electrode (e.g., a cathode electrode CE in FIG. 9) common to the light emitting elements LEL of the plurality of pixels PX. For example, the driving voltage may be a high potential voltage for driving the light emitting element LEL, and the common voltage may be a low potential voltage for driving the light emitting element LEL.

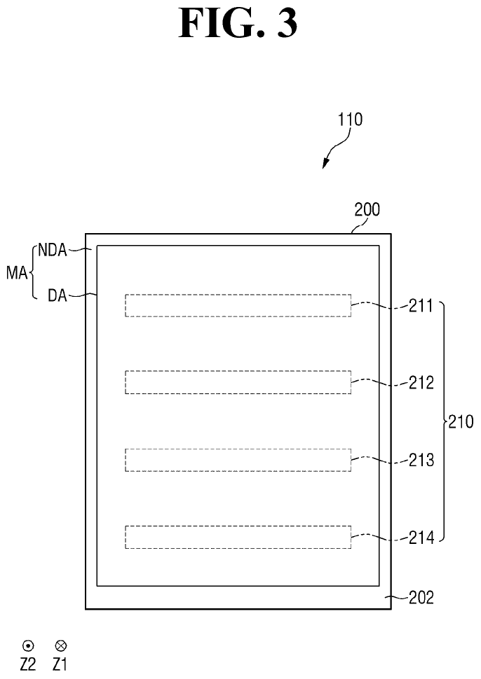

FIG. 2 is a plan view illustrating a front surface 201 of the display panel 110 according to an embodiment. FIG. 3 is a plan view illustrating a rear surface 202 of the display panel 110 according to an embodiment. In FIG. 2, components disposed on the front surface 201 of the display panel 110 are illustrated as solid lines, and components disposed on the rear surface 202 of the display panel 110 are illustrated as dotted lines. In FIG. 3, components disposed on the rear surface 202 of the display panel 110 are illustrated as solid lines, and components disposed on the front surface 201 of the display panel 110 are illustrated as dotted lines.

Referring to FIG. 2, the display panel 110 may be an organic light emitting diode on silicon (OLEDoS) panel using the semiconductor wafer substrate 200 as a base. For example, the display panel 110 may include the semiconductor wafer substrate 200. A complementary metal oxide semiconductor (CMOS) layer 910 (see FIG. 9) including a CMOS forming the display driving circuits 210 may be disposed on the front surface 201 of the semiconductor wafer substrate 200. The CMOS forming the display driving circuits 210 may include a field effect transistor, for example, an n-type metal oxide semiconductor field effect transistor (MOSFET) and/or a p-type MOSFET. Herein, the CMOS layer 910 may be referred to as a “first driving element layer”.

According to an embodiment, a plurality of display driving circuits 210 driven independently of each other are embedded in one display panel 110. Each of the plurality of display driving circuits 210 may output signals for driving the display panel 110 (e.g., signals for driving the pixel driving circuit (PC in FIG. 7)) and voltages.

The plurality of display driving circuits 210 are disposed at intervals in the CMOS layer (910 in FIG. 9) and are disposed to correspond to the display area DA. Each of the plurality of display driving circuits 210 controls the pixel driving circuits (PC in FIG. 7) of the display area DA. All of the plurality of display driving circuits 210 may include identical circuit components. For example, the plurality of display driving circuits 210 include the same circuits as each other and are configured to perform the same functions. In other words, one display panel 110 includes the plurality of display driving circuits 210. However, the display panel 110 may control the pixel driving circuits PC using only one display driving circuit among the plurality of display driving circuits 210. The reason for why the display panel 110 according to an embodiment includes the plurality of display driving circuits 210 is to increase a ratio of non-defective products of the display panel 110 among the number of net dies included in one semiconductor wafer 600. In other words, by including the plurality of display driving circuits 210, the yield of individual dies can be increased. According to an embodiment, the display panel 110 manufactured from one die may be shipped as a non-defective product if at least one display driving circuit among the plurality of display driving circuits 210 disposed on the front surface 201 of the semiconductor wafer substrate 200 is not defective. In the display device 10 according to an embodiment of the present disclosure, since the display panel 110 may be easily repaired, manufacturing costs may be reduced.

According to an embodiment, the plurality of display driving circuits 210 may include two or more display driving circuits 210. For example, the plurality of display driving circuits 210 include a first display driving circuit 211 and a second display driving circuit 212. The first display driving circuit 211 includes a first circuit 410 (see FIG. 4) disposed to correspond to a first area of the display area DA in the CMOS layer 910. The second display driving circuit 212 includes a second circuit 420 (see FIG. 4) disposed to correspond to a second area of the display area DA in the CMOS layer 910. The first circuit 410 and the second circuit 420 may be the same circuit. In addition, the plurality of display driving circuits 210 may further include a third display driving circuit 213 and a fourth display driving circuit 214, but the present disclosure is not limited thereto. The third display driving circuit 213 includes a third circuit 430 (see FIG. 4) disposed to correspond to a third area of the display area DA in the CMOS layer 910. The fourth display driving circuit 214 includes a fourth circuit 440 (see FIG. 4) disposed to correspond to a fourth area of the display area DA in the CMOS layer 910. The first to fourth circuits 410, 420, 430, and 440 may be the same circuit.

Referring to FIG. 3, a transistor layer (940 in FIG. 9) and a light emitting element layer (950 in FIG. 9) are disposed on the rear surface 202 of the semiconductor wafer substrate 200. The transistor layer 940 may include pixel driving circuits PC for driving a light emitting element (LEL in FIG. 9), lines (e.g., gate lines, data lines, and light emitting control lines) connected to the pixel driving circuits PC, and fan-out lines FL extending from the lines and disposed to correspond to the non-display area NDA. The fan-out lines FL may be electrically connected to the plurality of display driving circuits 210 disposed on the front surface 201 of the semiconductor wafer substrate 200 through contact holes (450 in FIG. 4 and CT210 and CT220 in FIG. 9) penetrating through the semiconductor wafer substrate 200. In other words, the pixel driving circuits PC may be electrically connected to the plurality of display driving circuits 210 through the contact holes (450 in FIG. 4 and CT210 and CT220 in FIG. 9). For example, the plurality of display driving circuits 210 may include the first to fourth display driving circuits 211, 212, 213, and 214, and in this case, the contact hole 450 may include a first contact hole (451 in FIG. 4), a second contact hole (452 in FIG. 4), a third contact hole (453 in FIG. 4), and a fourth contact hole (454 in FIG. 4). Herein, the transistor layer 940 may be referred to as a “second driving element layer”.

The first contact hole 451 may connect the first display driving circuit 211 and the plurality of pixel driving circuits PC. In other words, the first contact hole 451 may be used to connect the first display driving circuit 211 to the display panel 110. For example, the first contact hole 451 may be disposed in the non-display area NDA to electrically connect the first display driving circuit 211 and the fan-out lines (FL in FIG. 4).

The second contact hole 452 may connect the second display driving circuit 212 and the plurality of pixel driving circuits PC. In other words, the second contact hole 452 may be used to connect the second display driving circuit 212 to the display panel 110. For example, the second contact hole 452 may be disposed in the non-display area NDA to electrically connect the second display driving circuit 212 and the fan-out lines (FL in FIG. 4).

The third contact hole 453 may connect the third display driving circuit 213 and the plurality of pixel driving circuits PC. In other words, the third contact hole 453 may be used to connect the third display driving circuit 213 to the display panel 110. For example, the third contact hole 453 may be disposed in the non-display area NDA to electrically connect the third display driving circuit 213 and the fan-out lines (FL in FIG. 4).

The fourth contact hole 454 may connect the fourth display driving circuit 214 and the plurality of pixel driving circuits PC. In other words, the fourth contact hole 454 may be used to connect the fourth display driving circuit 214 to the display panel 110. For example, the fourth contact hole 454 may be disposed in the non-display area NDA to electrically connect the fourth display driving circuit 214 and the fan-out lines (FL in FIG. 4).

The pixel driving circuits PC may be circuits that drive each of the plurality of pixels PX disposed in the display area DA, and may include a plurality of thin film transistors (T1, T2, T3, T4, and T5 in FIG. 7) and one or more capacitors (C1 and C2 in FIG. 7). The plurality of thin film transistors T1, T2, T3, T4, and T5 included in the pixel driving circuits PC may include oxide-based thin film transistors.

Herein, the front surface 201 of the semiconductor wafer substrate 200 indicates a surface facing a first direction Z1 (e.g., a first normal direction) from the semiconductor wafer substrate 200. The rear surface 202 of the semiconductor wafer substrate 200 indicates a surface facing a second direction Z2 (e.g., a second normal direction) opposite to the first direction Z1 from the semiconductor wafer substrate 200. Herein, the first direction Z1 indicates a normal direction in which field effect transistors (e.g., MOSFETs) of the CMOS layer 910 are formed from the semiconductor wafer substrate 200. Herein, the second direction Z2 indicates a normal direction opposite to the first direction Z1.

FIG. 4 is a configuration block diagram of the display device 10 according to an embodiment. In FIG. 4, for convenience of explanation, the first to fourth display driving circuits 211, 212, 213, and 214 and the display panel 110 are illustrated separately from each other, but the first to fourth display driving circuits 211, 212, 213, and 214 are embedded in the CMOS layer (910 in FIG. 9) of the display panel 110. Similarly, in FIG. 4, for convenience of explanation, the fan-out lines FL and the contact hole 450 are illustrated separately from the display panel 110, but the fan-out lines FL and the contact hole 450 may be disposed in the non-display area NDA of the display panel 110.

Referring to FIG. 4, the first display driving circuit 211, the second display driving circuit 212, the third display driving circuit 213, and the fourth display driving circuit 214 are embedded in the display panel 110 according to an embodiment. The first to fourth display driving circuits 211, 212, 213, and 214 may be formed on the CMOS layer 910 disposed on the front surface 201 of the semiconductor wafer substrate 200.

The first display driving circuit 211 includes a first timing controller 411, a first gate driver 412, a first emission control driver 413, and a first data driver 414 as the first circuit 410. The first timing controller 411 controls driving timings of the first gate driver 412, the first emission control driver 413, and the first data driver 414. The first timing controller 411 aligns a digital video data signal DATA (see FIG. 6) (hereinafter referred to as “data signal”) input from the outside depending on the resolution and driving frequency of the display panel 110. The first timing controller 411 supplies the aligned data signal DATA to the first data driver 414. The first gate driver 412 drives gate lines GL (see FIG. 6) of the display panel 110 under control of the first timing controller 411. The first data driver 414 drives data lines DL (see FIG. 6) of the display panel 110 under control of the first timing controller 411. The first emission control driver 413 drives emission control lines EML (see FIG. 6) of the display panel 110 under control of the first timing controller 411. The gate lines GL, the data lines DL, and the emission control lines EML of the display panel 110 are connected to the pixel driving circuit PC through the first contact hole 451 and the fan-out lines FL. Accordingly, the first display driving circuit 211 may control the pixel driving circuits PC.

The second display driving circuit 212 includes a second timing controller 421, a second gate driver 422, a second emission control driver 423, and a second data driver 424 as the second circuit 420. The second circuit 420 of the second display driving circuit 212 is substantially the same as the first circuit 410 of the first display driving circuit 211. Therefore, the description of the second circuit 420 will be replaced with the description of the first circuit 410. For example, the second timing controller 421 aligns a digital video data signal DATA input from the outside depending on the resolution and driving frequency of the display panel 110, and supplies the aligned data signal DATA to the second data driver 424. The gate lines GL, the data lines DL, and the emission control lines EML of the display panel 110 are connected to the pixel driving circuit PC through the second contact hole 452 and the fan-out lines FL. Accordingly, the second display driving circuit 212 may control the pixel driving circuits PC.

The third display driving circuit 213 includes a third timing controller 431, a third gate driver 432, a third emission control driver 433, and a third data driver 434 as the third circuit 430. The third circuit 430 of the third display driving circuit 213 is substantially the same as the first circuit 410 of the first display driving circuit 211. Therefore, the description of the third circuit 430 will be replaced with the description of the first circuit 410. The gate lines GL, the data lines DL, and the emission control lines EML of the display panel 110 are connected to the pixel driving circuit PC through the third contact hole 453 and the fan-out lines FL. Accordingly, the third display driving circuit 213 may control the pixel driving circuits PC.

The fourth display driving circuit 214 includes a fourth timing controller 441, a fourth gate driver 442, a fourth emission control driver 443, and a fourth data driver 444 as the fourth circuit 440. The fourth circuit 440 of the fourth display driving circuit 214 is substantially the same as the first circuit 410 of the first display driving circuit 211. Therefore, the description of the fourth circuit 440 will be replaced with the description of the first circuit 410. The gate lines GL, the data lines DL, and the emission control lines EML of the display panel 110 are connected to the pixel driving circuit PC through the fourth contact hole 454 and the fan-out lines FL. Accordingly, the fourth display driving circuit 214 may control the pixel driving circuits PC.

According to an embodiment, the functions of the first to fourth display driving circuits 211, 212, 213, and 214 may be substantially the same. Therefore, operation timings of the first to fourth display driving circuits 211, 212, 213, and 214 may be substantially synchronized. Therefore, according to an embodiment of the present disclosure, even if some of the first to fourth display driving circuits 211, 212, 213, and 214 are determined to be defective, the display panel 110 may be driven using the remaining display driving circuits determined to be non-defective.

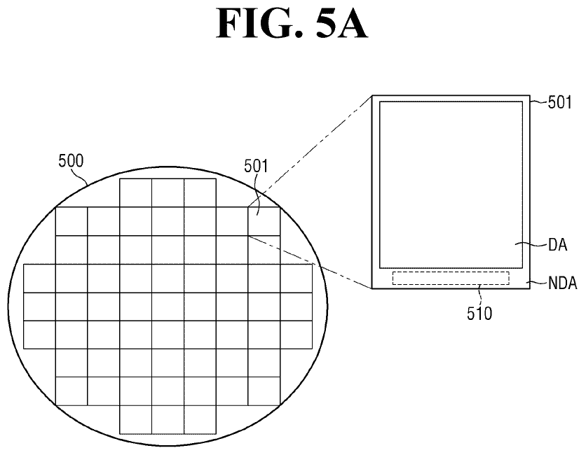

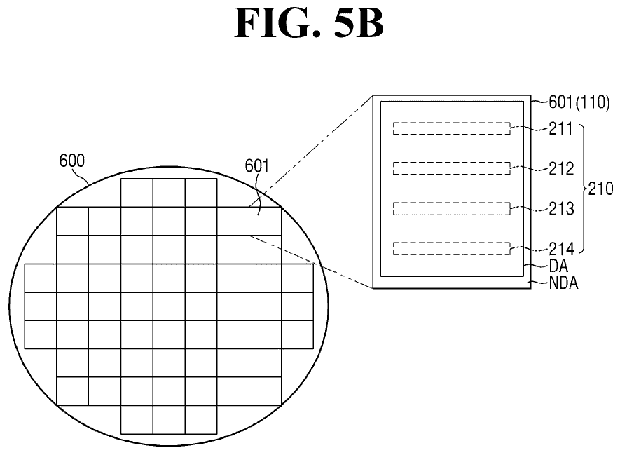

FIG. 5A is a view illustrating a semiconductor wafer 500 for manufacturing a display panel according to a comparative example. FIG. 5B is a view illustrating a semiconductor wafer 600 for manufacturing a display panel 110 according to an embodiment.

Referring to FIG. 5A, a semiconductor wafer 500 according to a comparative example may be a semiconductor wafer 500 for OLEDoS. According to the comparative example, a net die included in one semiconductor wafer 500 may include about 76 dies. Considering that the net die of the semiconductor wafer 500 for manufacturing a general driving IC includes about 1500 to about 2000 dies, this is a significant reduction in the number of dies. According to the comparative example, as each die 501 included in one semiconductor wafer 500 is designed to include one display driving circuit 510, the yield of dies determined to be non-defective may decrease.

On the other hand, referring to FIG. 5B, in a semiconductor wafer 600 according to an embodiment, the net die included in one semiconductor wafer 600 includes about 76 dies, but as a portion (e.g., one display panel 110) of a semiconductor wafer corresponding to one die 601 is designed to include a plurality of display driving circuits 210, the yield of dies 601 determined to be non-defective increase compared to the comparative example.

FIG. 6 is a block diagram illustrating a connection between the display panel 110 and any one of a plurality of display driving circuits according to an embodiment. For example, a timing controller 610 illustrated in FIG. 6 may be the first timing controller 411 of the first display driving circuit 211. For example, a gate driver 620 illustrated in FIG. 6 may be the first gate driver 412 of the first display driving circuit 211. For example, an emission control driver 630 illustrated in FIG. 6 may be the first emission control driver 413 of the first display driving circuit 211. For example, a data driver 640 illustrated in FIG. 6 may be the first data driver 414 of the first display driving circuit 211.

Referring to FIG. 6, the display panel 110 may include a display area DA and a non-display area NDA.

The display area DA may include a plurality of pixels PX, a plurality of driving voltage lines VDL, a plurality of common voltage lines (VSL in FIG. 7), a plurality of gate lines GL, a plurality of emission control lines EML, and a plurality of data lines DL connected to each pixel PX.

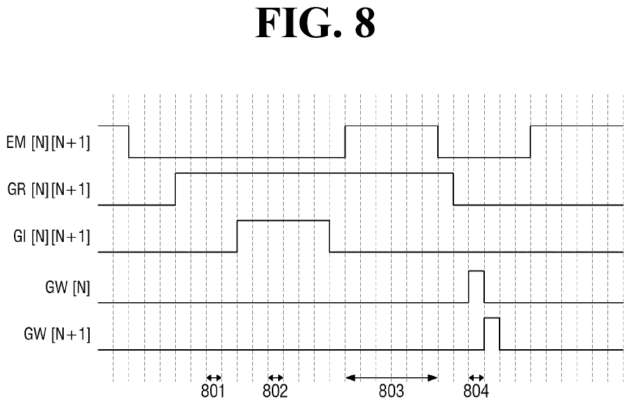

Each of the plurality of pixels PX may be connected to the gate line GL, the data line DL, the emission control line EML, the driving voltage line VDL, and the common voltage line VSL. Each of the plurality of pixels PX includes a light emitting element LEL, and may include a plurality of thin film transistors and one or more capacitors as a pixel driving circuit PC for driving the light emitting element LEL. The pixel driving circuit PC included in each pixel PX will be described later in detail with reference to FIGS. 7 and 8.

The display panel 110 may include a plurality of display driving circuits 210. Each display driving circuit 210 may include a timing controller 610, a gate driver 620, an emission control driver 630, and a data driver 640.

The timing controller 610 may receive a data signal DATA and timing signals from the circuit board 120. Based on the timing signals, the timing controller 610 may control an operation timing of the data driver 640 by generating a data control signal DCS, control an operation timing of the gate driver 620 by generating a gate control signal GCS, and control an operation timing of the emission control driver 630 by generating an emission control signal ECS.

The data driver 640 may convert the data signal DATA into analog data voltages and supply the analog data voltages to the data lines DL. The gate signals of the gate driver 620 may select the pixels PX to which the data voltage is supplied, and the selected pixels PX may receive the data voltage through the data lines DL.

The power supply unit 130 may be disposed on the circuit board 120, and may supply a power voltage to the display driving circuits 210 and the display panel 110. The power supply unit 130 may generate a driving voltage and supply the driving voltage to the driving voltage line VDL. In addition, the power supply unit 130 may generate a common voltage and supply the common voltage to a common electrode (e.g., a cathode electrode CE in FIG. 9) common to the light emitting elements LEL of the plurality of pixels PX.

The gate driver 620 may supply gate signals (GR, GI, and GW in FIG. 7) to the gate lines GL.

The emission control driver 630 may supply emission signals (EM in FIG. 7) to the emission control lines EML.

FIG. 7 is a circuit diagram of a pixel PX of the display device 10 according to an embodiment.

Referring to FIG. 7, the pixel PX may include a light emitting element LEL (e.g., an organic light emitting diode) as a display element and a pixel driving circuit PC connected to the light emitting element LEL. The pixel driving circuit PC may include first, second, third, fourth and fifth thin film transistors T1, T2, T3, T4, and T5, and first and second capacitors C1 and C2. The first thin film transistor T1 may be a driving transistor whose source-drain current is determined according to a gate-source voltage, and each of the second to fifth thin film transistors T2 to T5 may be a switching transistor that is turned on/off according to a gate-source voltage, substantially a gate voltage. The first to fifth thin film transistors T1, T2, T3, T4, and T5 may be oxide-based thin film transistors. Depending on the type (p-type or n-type) and/or operating conditions of the transistor, a first electrode of each of the first to fifth thin film transistors T1, T2, T3, T4, and T5 may be a source electrode SE (see FIG. 9) or a drain electrode DE (see FIG. 9), and a second electrode of each of the first to fifth thin film transistors T1, T2, T3, T4, and T5 may be an electrode different from the first electrode. For example, when the first electrode is the source electrode SE, the second electrode may be the drain electrode DE.

The pixel PX may be connected to a first gate line GWL through which a first gate signal GW is transmitted, a second gate line GIL through which a second gate signal GI is transmitted, a third gate line GRL through which a third gate signal GR is transmitted, an emission control line EML through which an emission signal EM is transmitted, and a data line DL through which a data signal DATA is transmitted. A driving voltage line VDL may be used to transmit a first driving voltage ELVDD to the first thin film transistor T1. An initialization voltage line VIL may be used to transmit an initialization voltage VINT to the light emitting element LEL (e.g., the organic light emitting diode). A reference voltage line VRL may transmit a reference voltage VREF to the gate electrode of the first thin film transistor T1. In addition, depending on the pixel structure, the aforementioned initialization voltage line VIL may include a plurality of initialization voltage lines VIL (e.g., a first initialization voltage line VIL and a second initialization voltage line VIL) that transmit initialization voltages VINT of different magnitudes.

The plurality of first to fifth thin film transistors T1, T2, T3, T4, and T5 may include an oxide semiconductor material. The oxide semiconductor has high carrier mobility and a low leakage current, and thus, a voltage drop is not large even when a driving time is long. In other words, since the oxide semiconductor does not significantly change the color of an image due to a voltage drop even when driven at a low frequency, the oxide semiconductor may be driven at a low frequency. Therefore, since the plurality of first to fifth thin film transistors T1, T2, T3, T4, and T5 include the oxide semiconductor material, the generation of leakage current may be prevented and power consumption may be reduced. In addition, since oxide-based semiconductor transistors do not require a crystallization process by excimer laser annealing (ELA), which is a process of forming low-temperature polycrystalline silicon (LTPS) semiconductor transistors, the manufacturing costs thereof may be reduced.

Furthermore, since the oxide semiconductor is sensitive to light, fluctuations in the amount of current or the like may occur due to external light. Therefore, to enhance the absorption or reflection of external light, a metal layer may be disposed on a lower side of the oxide semiconductor. At least some of the first to fifth thin film transistors T1, T2, T3, T4, and T5 may be double gate transistors having a lower gate electrode (e.g., a counter gate electrode). The illustrated example illustrates that the first thin film transistor T1 is a double gate transistor, but the present disclosure is not limited thereto.

The first thin film transistor T1 includes a gate electrode connected to a first node N1 (or a gate node), a first electrode connected to a second node N2, and a second electrode connected to a third node N3. The second node N2 may be a node connected to a second electrode (e.g., a source electrode) of the fifth thin film transistor T5. The third node N3 may be a node connected to an anode electrode (ANE in FIG. 9) (e.g., a pixel electrode) of the light emitting element LEL. The first thin film transistor T1 may function as a driving transistor, and may receive the data signal DATA according to a switching operation of a second thin film transistor T2 and control the magnitude (e.g., the amount of current) of a driving current Id flowing to the light emitting element LEL.

The second thin film transistor T2 (e.g., a data write transistor) includes a gate electrode connected to the first gate line GWL, a first electrode connected to the data line DL, and a second electrode connected to the first node N1 (or the gate electrode of the first thin film transistor T1). The second thin film transistor T2 may be turned on according to the first gate signal GW transmitted to the first gate line GWL to electrically connect the data line DL and the first node N1, and may provide the data signal DATA transmitted through the data line DL to the first node N1.

The third thin film transistor T3 (e.g., a first initialization transistor) includes a gate electrode connected to the third gate line GRL, a first electrode connected to the reference voltage line VRL, and a second electrode connected to the first node N1 (or the gate electrode of the first thin film transistor T1). The third thin film transistor T3 may be turned on according to the third gate signal GR transmitted through the third gate line GRL to provide the reference voltage VREF transmitted through the reference voltage line VRL to the first node N1.

The fourth thin film transistor T4 (e.g., a second initialization transistor) includes a gate electrode connected to the second gate line GIL, a first electrode connected to the third node N3 (or the second electrode of the first thin film transistor T1), and a second electrode connected to the initialization voltage line VIL. The fourth thin film transistor T4 may be turned on according to the second gate signal GI transmitted through the second gate line GIL to provide the initialization voltage VINT transmitted through the initialization voltage line VIL to the third node N3.

The fifth thin film transistor T5 (e.g., an emission control transistor) includes a gate electrode connected to the emission control line EML, a first electrode connected to the driving voltage line VDL, and a second electrode connected to the second node N2 (or the first electrode of the first thin film transistor T1). The fifth thin film transistor T5 may be turned on or off according to the emission signal EM transmitted through the emission control line EML.

The first capacitor C1 may be disposed between the first node N1 and the third node N3. The first capacitor C1, which is a storage capacitor, may store a voltage corresponding to a threshold voltage of the first thin film transistor T1 and a data signal DATA.

The second capacitor C2 may be disposed between the third node N3 and the driving voltage line VDL.

The light emitting element LEL may include a pixel electrode (e.g., an anode electrode ANE in FIG. 9) and a common electrode (e.g., a cathode electrode CE in FIG. 9) facing the pixel electrode, and the common electrode may be applied with a second driving voltage ELVSS. The common electrode of the light emitting element LEL may be connected to the common voltage line VSL transmitting the second driving voltage ELVSS. The common electrode of the light emitting element LEL may be commonly connected to the plurality of pixels PX.

FIG. 8 is a view illustrating a driving timing of the pixel driving circuit PC illustrated in FIG. 7.

In FIG. 8, EM[N][N+1] is a driving timing of an emission signal EM supplied to the pixel driving circuit PC of the pixel PX disposed in an N-th row and an N+1-th row of a plurality of pixels. In FIG. 8, GR[N][N+1] is a driving timing of a third gate signal GR supplied to the pixel driving circuit PC of the pixel PX disposed in the N-th row and the N+1-th row. In FIG. 8, GI[N][N+1] is a driving timing of a second gate signal GI supplied to the pixel driving circuit PC of the pixel PX disposed in the N-th row and the N+1-th row. In FIG. 8, GW[N] is a driving timing of a first gate signal GW supplied to the pixel driving circuit PC of the pixel PX disposed in the N-th row. In FIG. 8, GW[N+1] is a driving timing of a first gate signal GW supplied to the pixel driving circuit PC of the pixel PX disposed in the N+1-th row.

Referring to FIG. 8, the pixel driving circuit PC may operate in a first period 801, a second period 802, a third period 803, and a fourth period 804 separated from each other during one frame. The first, second, third and fourth periods 801-804 may occur in order.

Hereinafter, an operation of the pixel driving circuit PC of the pixel PX disposed in the N-th row will be mainly described.

The pixel driving circuit PC receives the third gate signal GR in a gate-on voltage state (e.g., a high state) in the first period 801. In the first period 801, the first gate signal GW, the second gate signal GI, and the emission signal EM are in a gate-off voltage state (e.g., a low state). The third thin film transistor T3 is turned on in response to the third gate signal GR and transmits the reference voltage VREF to the first node N1. Accordingly, the first node N1 is initialized to the reference voltage VREF.

The pixel driving circuit PC receives the second gate signal GI and the third gate signal GR in a gate-on voltage state (e.g., a high state) in the second period 802. In the second period 802, the first gate signal GW and the emission signal EM are in a gate-off voltage state (e.g., a low state). The fourth thin film transistor T4 is turned on in response to the second gate signal GI and transmits the initialization voltage VINT to the third node N3. Accordingly, the third node N3 is initialized to the initialization voltage VINT. In the second period 802, the third thin film transistor T3 maintains a turned-on state.

The pixel driving circuit PC receives the emission signal EM and the third gate signal GR in a gate-on voltage state (e.g., a high state) in the third period 803. In the third period 803, the first gate signal GW and the second gate signal GI are in a gate-off voltage state (e.g., a low state). The fifth thin film transistor T5 may be turned on in response to the emission signal EM, and may transmit the first driving voltage ELVDD to the second node N2. The third thin film transistor T3 maintains a turned-on state in the third period 803, and thus, the first node N1 maintains the reference voltage VREF. The first thin film transistor T1 forms a current path connecting the second node N2 and the third node N3. The first thin film transistor T1 may be turned off when a gate voltage thereof is less than or equal to a difference (VREF-Vth) between the reference voltage VREF and a threshold voltage Vth of the first thin film transistor T1. The first capacitor C1 may store a voltage including the threshold voltage Vth of the first thin film transistor T1. The third period 803 may be a compensation period for compensating for the threshold voltage Vth of the first thin film transistor T1.

The pixel driving circuit PC receives the first gate signal GW in a gate-on voltage state (e.g., a high state) in the fourth period 804. In the fourth period 804, the second gate signal GI, the third gate signal GR, and the emission signal EM are in a gate-off voltage state (e.g., a low state). The second thin film transistor T2 may be turned on in response to the first gate signal GW and may transmit the data signal DATA to the first node N1. Accordingly, the first node N1 has a data voltage in which the threshold voltage Vth of the first thin film transistor T1 is compensated.

After the fourth period 804, the pixel driving circuit PC receives the emission signal EM, which is in a gate-on voltage state (e.g., a high state), and the first thin film transistor T1 supplies a driving current Id corresponding to the data signal DATA to the light emitting element LEL.

FIG. 9 is a cross-sectional view of a portion of a display area DA of a display panel 110 according to an embodiment.

Referring to FIG. 9, the display panel 110 includes a semiconductor wafer substrate 200, and a CMOS layer 910 including a plurality of display driving circuits 210 is disposed on a front surface 201 of the semiconductor wafer substrate 200. A transistor layer 940 including transistors constituting the plurality of pixel driving circuits PC, a light emitting element layer 950, and an encapsulation layer 960 are disposed on a rear surface 202 of the semiconductor wafer substrate 200. In other words, the CMOS layer 910 is stacked in the first direction Z1 from the semiconductor wafer substrate 200, and the transistor layer 940, the light emitting element layer 950, and the encapsulation layer 960 are sequentially stacked in the second direction Z2 from the semiconductor wafer substrate 200.

The semiconductor wafer substrate 200 may be a silicon substrate, a germanium substrate, or a silicon-germanium substrate. The semiconductor wafer substrate 200 may be a substrate doped with first-type impurities.

The CMOS layer 910 including a MOSFET and line electrodes connected to the MOSFET is disposed in the first direction Z1, which is a direction from the semiconductor wafer substrate 200 toward the front surface 201 thereof. In other words, the CMOS layer 910 may be disposed on top of the semiconductor wafer substrate 200. The CMOS layer 910 includes an n-type MOSFET and/or a p-type MOSFET. The first type impurity may be a p-type impurity, and the second type impurity may be an n-type impurity. Alternatively, the first type impurity may be an n-type impurity, and the second type impurity may be a p-type impurity.

Herein, an n-type MOSFET MOS included in the CMOS layer 910 will be described as an example. The n-type MOSFET MOS may include a well region W1 doped with an n-type impurity in a substrate doped with a p-type impurity. The well region W1 may include a first low-concentration impurity region LDD1 and a second low-concentration impurity region LDD2 having a relatively lower impurity concentration than other portions of the well region W1. The first low-concentration impurity region LDD1 may form a source region S1, and the second low-concentration impurity region LDD2 may form a drain region D1. A channel CH disposed to overlap a gate G1 is formed between the first low-concentration impurity region LDD1 and the second low-concentration impurity region LDD2. An oxide film GI1, which is an insulating layer, may be disposed between the gate G1 and the well region W1.

MOSFETs MOS disposed on the front surface 201 of the semiconductor wafer substrate 200 constitute the plurality of display driving circuits 210. The display driving circuits 210 are disposed to overlap the plurality of pixels PX in the display area DA of the display panel 110. For example, circuits formed by a combination of the MOSFETs MOS disposed on the front surface 201 of the semiconductor wafer substrate 200 may constitute the first display driving circuit 211, the second display driving circuit 212, the third display driving circuit 213, and the fourth display driving circuit 214 described with reference to FIG. 4.

One or more insulating layers 911 and 912 may be disposed on the MOSFETs MOS. For example, one or more insulating layers 911 and 912 are disposed in the first direction Z1 from the MOSFETs MOS. Line electrodes CE100 penetrating through a portion of the insulating layer 911 and connecting the MOSFETs MOS to each other are disposed in the first direction Z1 from the MOSFETs MOS. The line electrodes CE100 connecting the MOSFETs MOS to each other may be electrically connected to the MOSFET MOS through the contact holes CT110 and CT120 penetrating through the insulating layer 911. Portions of the line electrodes CE100 may be provided in the insulating layer 912. For example, the line electrodes CE100 may include a first line electrode CE110 connected to the source region S1 of the MOSFET MOS and a second line electrode CE120 connected to the drain region D1 of the MOSFET MOS.

Some of the line electrodes CE100 disposed on the MOSFETs MOS may be electrically connected to the transistor layer 940 disposed on the rear surface 202 of the semiconductor wafer substrate 200 through the contact holes CT210 and CT220 (e.g., 450 in FIG. 4) penetrating through the semiconductor wafer substrate 200. In other words, some of the line electrodes CE100 may be connected to the thin film transistor TFT1 (e.g., T1, T2, T3, T4, and T5 in FIG. 5) constituting the plurality of pixel driving circuits PC. Although FIG. 9 illustrates one contact hole CT210 or CT220 penetrating through the semiconductor wafer substrate 200, the number of contact holes CT210 and CT220 may be plural, and the contact holes CT210 and CT220 may include the first to fourth contact holes 451, 452, 453, and 454 as described with reference to FIG. 4. For example, the contact hole CT210 or CT220 may include a plurality of first contact holes 451 connecting the first display driving circuit 211 and the plurality of pixel driving circuits PC, a plurality of second contact holes 452 connecting the second display driving circuit 212 and the plurality of pixel driving circuits PC, a plurality of third contact holes 453 connecting the third display driving circuit 213 and the plurality of pixel driving circuits PC, and a plurality of fourth contact holes 454 connecting the fourth display driving circuit 214 and the plurality of pixel driving circuits PC.

A first cover window 930 may be disposed in the first direction Z1 from the CMOS layer 910. For example, the first cover window 930 may include a glass material, but the present disclosure is not limited thereto. At least one protective layer may be further disposed between the first cover window 930 and the CMOS layer 910. The protective layer may include, for example, a protective film.

A transistor layer 940 including a thin film transistor TFT1 and connection electrodes CE210 and CE220 connected to the thin film transistor TFT1 is disposed in the second direction Z2, which is a direction from the semiconductor wafer substrate 200 toward the rear surface 202 thereof. In other words, the transistor layer 940 may be disposed on the bottom of the semiconductor wafer substrate 200.

The thin film transistors TFT1 disposed on the rear surface 202 of the semiconductor wafer substrate 200 constitute a plurality of pixel driving circuits PC, and the pixel driving circuits PC are configured to drive the light emitting element LEL. For example, the thin film transistors TFT1 disposed on the rear surface 202 of the semiconductor wafer substrate 200 may constitute the first to fifth thin film transistors T1, T2, T3, T4, and T5 described with reference to FIG. 7.

The thin film transistor TFT1 (e.g., T1, T2, T3, T4, and T5 in 7) includes an active layer ACT, a gate electrode GE, a drain electrode DE, and a source electrode SE disposed on the rear surface 202 of the semiconductor wafer substrate 200. The active layer ACT includes an oxide semiconductor material.

The active layer ACT of the thin film transistor TFT1 includes a source region, a drain region, and a channel region between the source region and the drain region. The source region and the drain region may be regions having conductivity by doping an oxide semiconductor with ions or impurities. A buffer layer BF may be disposed between the active layer ACT of the thin film transistor TFT1 and the rear surface 202 of the semiconductor wafer substrate 200. For example, the buffer layer BF may be in contact with the active layer ACT of the thin film transistor TFT1 and the rear surface 202 of the semiconductor wafer substrate 200.

The gate electrode GE of the thin film transistor TFT1 is disposed to overlap the channel region of the active layer ACT. A gate insulating film 941 may be disposed between the gate electrode GE and the channel region of the active layer ACT.

An interlayer insulating film 942 is disposed in the second direction Z2 from the gate electrode GE of the thin film transistor TFT1. A source electrode SE connected to the source region through a source contact hole CT310 penetrating through a portion of the interlayer insulating film 942 and a drain electrode DE connected to the drain region through a drain contact hole CT320 penetrating through a portion of the interlayer insulating film 942 are disposed in the second direction Z2 from the interlayer insulating film 942.

One or more insulating layers 943 and 944 are disposed in the second direction Z2 from the thin film transistors TFT1. The insulating layers 943 and 944 may include an inorganic insulating film and/or an organic insulating film. The connection electrodes CE210 and CE220 penetrating through portions of the insulating layers 943 and 944 may be disposed in the second direction Z2 from the thin film transistors TFT1. The connection electrodes CE210 and CE220 may connect the thin film transistors TFT1 to each other or electrically connect the thin film transistor TFT1 and the light emitting element LEL through the contact holes CT410 and CT420.

One or more capacitor electrodes CPE1 and CPE2 are disposed on the same layer as the connection electrodes CE210 and CE220, respectively. For example, the capacitor electrode CPE1 may be disposed on the same layer as the connection electrode CE210 and the capacitor electrode CPE2 may be disposed on the same layer as the connection electrode CE220. The capacitor electrodes CPE1 and CPE2 may be disposed to face each other.

In the transistor layer 940, some of the thin film transistors TFT1 may be connected to the CMOS layer 910 disposed on the front surface 201 of the semiconductor wafer substrate 200. In other words, some of the thin film transistors TFT1 may be connected to the plurality of display driving circuits 210 through the contact holes CT210 and CT220 penetrating through the semiconductor wafer substrate 200. Accordingly, the thin film transistors TFT1 disposed in the transistor layer 940 may receive the gate signals (GR, GI, and GWL in FIG. 7), the emission signal EM, and the data signal DATA from the plurality of display driving circuits 210 through the contact holes CT210 and CT220.

The light emitting element layer 950 including a light emitting element LEL is disposed in the second direction Z2 from the transistor layer 940. The light emitting element LEL includes an anode electrode ANE connected to the thin film transistor TFT1 through a contact hole CT510 penetrating through a portion of the insulating layer 944 of the transistor layer 940, a light emitting layer EL covering the anode electrode ANE, and a cathode electrode CE covering the light emitting layer EL.

According to an embodiment, the light emitting layer EL may include an intermediate layer (or a common layer). The intermediate layer may have a tandem structure including a plurality of intermediate layers for emitting different lights. For example, the intermediate layer may include a first intermediate layer for emitting light of a first color, a second intermediate layer for emitting light of a second color, and a third intermediate layer for emitting light of a third color. The first intermediate layer, the second intermediate layer, and the third intermediate layer may be sequentially stacked.

The first intermediate layer may have a structure in which a first hole transport layer, a first organic light emitting layer for emitting light of a first color, and a first electron transport layer are sequentially stacked. The second intermediate layer may have a structure in which a second hole transport layer, a second organic light emitting layer for emitting light of a third color, and a second electron transport layer are sequentially stacked. The third intermediate layer may have a structure in which a third hole transport layer, a third organic light emitting layer for emitting light of a second color, and a third electron transport layer are sequentially stacked.

A first charge generating layer for supplying charges to the second intermediate layer and supplying electrons to the first intermediate layer may be disposed between the first intermediate layer and the second intermediate layer. A second charge generating layer for supplying charges to the third intermediate layer and supplying electrons to the second intermediate layer may be disposed between the second intermediate layer and the third intermediate layer.

The first intermediate layer may be disposed on the anode electrodes ANE and the pixel defining film PDL, and may be disposed on a bottom surface of each trench formed between the pixels that are adjacent to each other. Due to the trench, the first to third intermediate layers may be disconnected between the pixels that are adjacent to each other. In other words, each of the plurality of trenches may be a structure for disconnecting the first to third intermediate layers of the light emitting layer EL between the pixels that are adjacent to each other.

The light emitting element layer 950 further includes the pixel defining film PDL that partitions a light emitting area of the light emitting element LEL and a spacer (or a separator) SP disposed on the pixel defining film PDL. The pixel defining film PDL and the spacer SP may be formed as an organic film made of an acryl resin, an epoxy resin, a phenolic resin, a polyamide resin, a polyimide resin, or the like. FIG. 9 illustrates that the pixel defining film PDL divides a light emitting area of a first pixel PX1 and a light emitting area of a second pixel PX2 as an example.

The encapsulation layer 960 covering the light emitting element LEL is disposed in the second direction Z2 from the light emitting element layer 950. The encapsulation layer 960 includes at least one inorganic film to prevent oxygen or moisture from permeating into the light emitting element layer 950. In addition, the encapsulation layer 960 includes at least one organic film to protect the light emitting element layer 950 from foreign materials such as dust. For example, the encapsulation layer 960 includes a first encapsulation inorganic film TFE1, an encapsulation organic film TFE2, and a second encapsulation inorganic film TFE3.

The first encapsulation inorganic film TFE1 may be disposed on the cathode electrode CE, which is the common electrode, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, or a polyimide resin.

A color filter layer CF including a color filter is disposed in the second direction Z2 from the encapsulation layer 960. The color filter may include a red color filter that transmits red light, a green color filter that transmits green light, and a blue color filter that transmits blue light, but the present disclosure is not limited thereto. The color filter layer CF is provided when the light emitting element LEL of the light emitting element layer 950 emits white light. If the light emitting element LEL of the light emitting element layer 950 directly emits red light, green light, and blue light, the color filter layer CF may be omitted.

A light control layer MLA including a refractive film RM is disposed in the second direction Z2 from the color filter layer CF. The refractive film RM may refract incident light so that the light emitted from the light emitting element layer 950 is directed toward a normal direction of the display panel 110 (e.g., the second direction Z2). Such a refractive film RM may also be referred to as a light control pattern.

A second cover window 970 may be disposed in the second direction Z2 from the light control layer MLA. The second cover window 970 may include a glass material, but the present disclosure is not limited thereto. At least one protective layer may be further disposed between the second cover window 970 and the light control layer MLA. The protective layer may include, for example, a protective film.

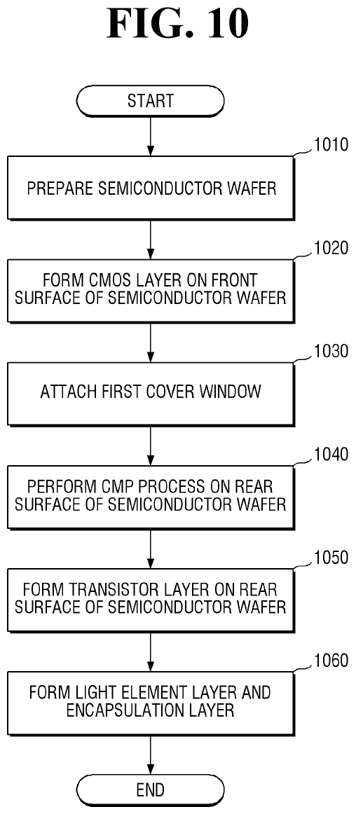

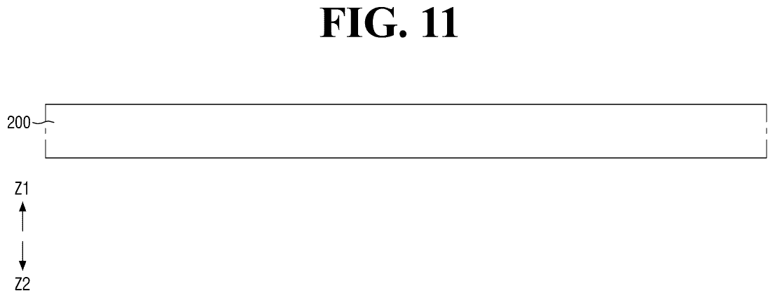

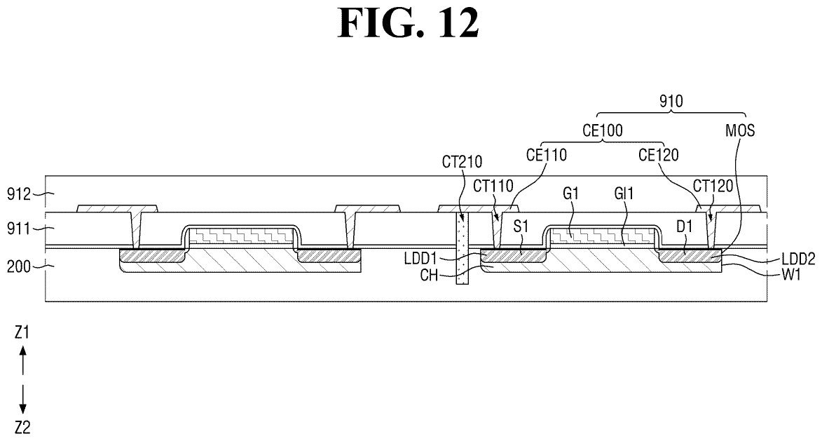

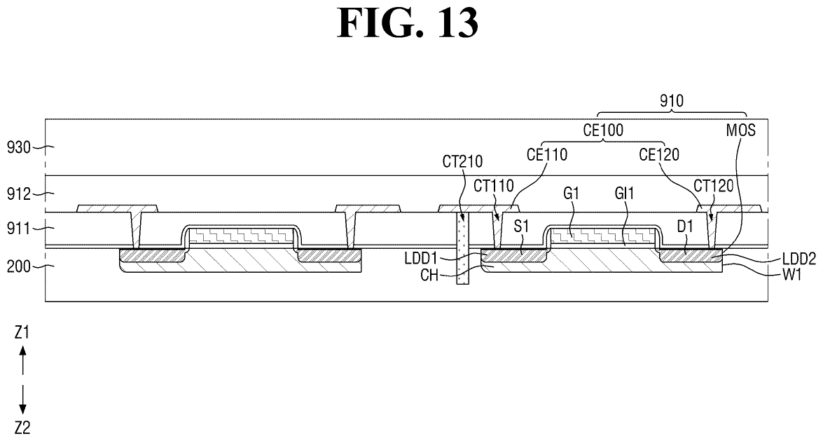

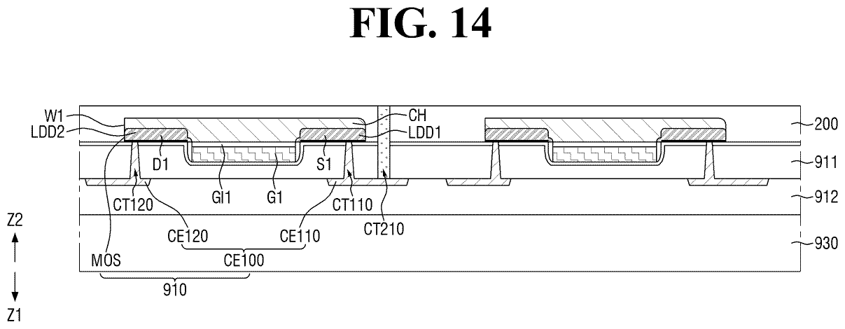

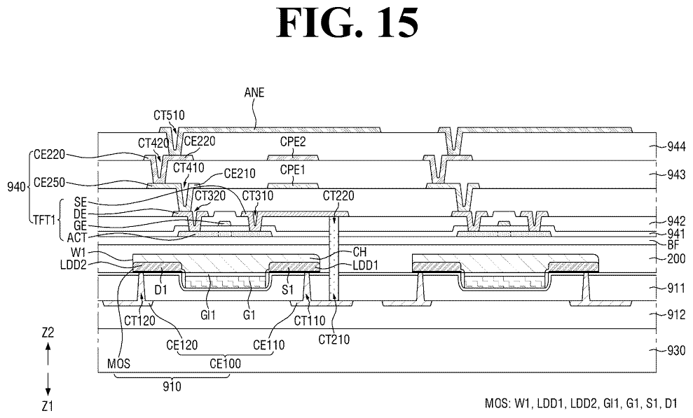

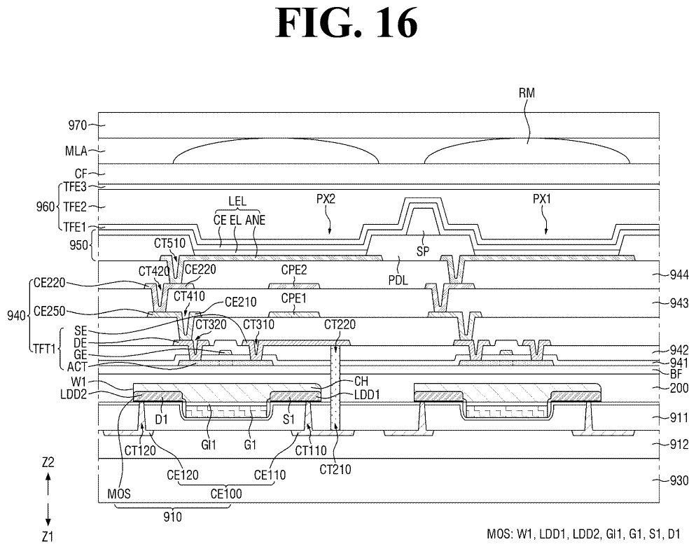

FIG. 10 is a flowchart illustrating at least a portion of a process of manufacturing a display device 10 according to an embodiment. FIG. 11 is a view illustrating a step of preparing a semiconductor wafer substrate 200. FIG. 12 is a view illustrating a step of forming a CMOS layer 910. FIG. 13 is a view illustrating a step of attaching a first cover window 930. FIG. 14 is a step illustrating a chemical mechanical polishing pad (CMP) process. FIG. 15 is a view illustrating a step of forming a transistor layer 940. FIG. 16 is a view illustrating steps of forming a light emitting element layer 950 and an encapsulation layer 960.

At least some process steps mentioned with reference to other drawings in the present disclosure may be added before or after each manufacturing process described with reference to FIGS. 10 to 16. In addition, a process of manufacturing a known semiconductor and/or a process of manufacturing a known display panel 110 may be added before or after each manufacturing process described with reference to FIGS. 10 to 16.

Hereinafter, at least a portion of a process of manufacturing the display device 10 according to an embodiment will be described with reference to FIGS. 10 to 16.

Referring to FIGS. 10 and 11, in step 1010, a semiconductor wafer substrate 200 may be prepared. The semiconductor wafer substrate 200 may be a silicon substrate, a germanium substrate, or a silicon-germanium substrate. The semiconductor wafer substrate 200 may be a substrate doped with first-type impurities.

Referring to FIGS. 10 and 12, in step 1020, a CMOS layer 910 may be formed on a front surface 201 of the semiconductor wafer substrate 200. The CMOS layer 910 including a MOSFET MOS and line electrodes CE100 connected to the MOSFET MOS is disposed in the first direction Z1, which is a direction from the semiconductor wafer substrate 200 toward the front surface 201 thereof. The CMOS layer 910 includes an n-type MOSFET and/or a p-type MOSFET. The first type impurity may be a p-type impurity, and the second type impurity may be an n-type impurity. Alternatively, the first type impurity may be an n-type impurity, and the second type impurity may be a p-type impurity.

MOSFETs MOS constitute a plurality of display driving circuits 210, and the display driving circuits 210 are disposed to overlap the plurality of pixels PX in the display area DA of the display panel 110. In other words, circuits formed by a combination of the MOSFETs MOS disposed on the front surface 201 of the semiconductor wafer substrate 200 may constitute the first display driving circuit 211, the second display driving circuit 212, the third display driving circuit 213, and the fourth display driving circuit 214 described with reference to FIG. 4.

Referring to FIGS. 10 and 13, in step 1030, a first cover window 930 may be attached onto the CMOS layer 910. For example, the first cover window 930 may include a glass material, but the present disclosure is not limited thereto. At least one protective layer may be further disposed between the first cover window 930 and the CMOS layer 910. The protective layer may include, for example, a protective film.

Referring to FIGS. 10 and 14, in step 1040, a chemical mechanical polishing pad (CMP) process may be performed on a rear surface 202 of the semiconductor wafer substrate 200. As the CMP process is performed on the semiconductor wafer substrate 200, portions of the contact holes (450 in FIG. 4, and CT210 and CT220 in FIG. 9) penetrating through the semiconductor wafer substrate 200 may be exposed through the rear surface 202. The contact hole 450 is configured to connect the CMOS layer 910, in other words, the plurality of display driving circuits 210 and thin film transistors TFT1 to be formed on the rear surface 202 of the semiconductor wafer substrate 200.

Referring to FIGS. 10 and 15, in step 1050, a transistor layer 940 may be formed on the rear surface 202 of the semiconductor wafer substrate 200. The thin film transistor TFT1 includes an active layer ACT, a gate electrode GE, a drain electrode DE, and a source electrode SE disposed on the rear surface 202 of the semiconductor wafer substrate 200. The active layer ACT includes an oxide semiconductor material.

An interlayer insulating film 942 is disposed in the second direction Z2 from the gate electrode GE of the thin film transistor TFT1. A source electrode SE penetrating through a portion of the interlayer insulating film 942 and connected to the source region and a drain electrode DE penetrating through a portion of the interlayer insulating film 942 and connected to the drain region are disposed in the second direction Z2 from the interlayer insulating film 942. A process of forming the source electrode SE and the drain electrode DE may include a line process of connecting the source electrode SE (or the drain electrode DE) of some thin film transistors TFT1 and the MOSFET MOS of the CMOS layer 910 disposed on the front surface 201 of the semiconductor wafer substrate 200 to each other through the contact holes CT210 and CT220.

One or more insulating layers 943 and 944 are disposed in the second direction Z2 from the thin film transistors TFT1. The insulating layers 943 and 944 may include an inorganic insulating film and/or an organic insulating film. The connection electrodes CE210 and CE220 penetrating through portions of the insulating layers 943 and 944 may be disposed in the second direction Z2 from the thin film transistors TFT1. The connection electrodes CE210 and CE220 may connect the thin film transistors TFT1 to each other or electrically connect the thin film transistor TFT1 and the light emitting element LEL. Capacitor electrodes CPE1 and CPE2 may be disposed on the same layer as the connection electrodes CE210 and CE220, respectively, and the capacitor electrodes CPE1 and CPE2 may be manufactured by the same process as the connection electrodes CE210 and CE220, respectively.

Referring to FIGS. 10 and 16, in step 1060, a light emitting element layer 950 and an encapsulation layer 960 may be formed on the transistor layer 940. A color filter layer CF, a light control layer MLA including a refractive film RM, and a second cover window 970 may be further disposed in the second direction Z2 from the encapsulation layer 960. The second cover window 970 may include a glass material, but the present disclosure is not limited thereto. At least one protective layer may be further disposed between the second cover window 970 and the light control layer MLA. The protective layer may include, for example, a protective film.

The display device 10 according to an embodiment may be a display device 10 included in a mobile electronic device. The display device 10 according to an embodiment may be included in a wearable device that is developed in the form of glasses or a helmet and focused at a distance close to the user's eyes. For example, the wearable device may be a head mounted display (HMD) device or AR glass. Such a wearable device provides a user with an augmented reality (hereinafter, referred to as “AR”) screen or a virtual reality (hereinafter, referred to as “VR”) screen.

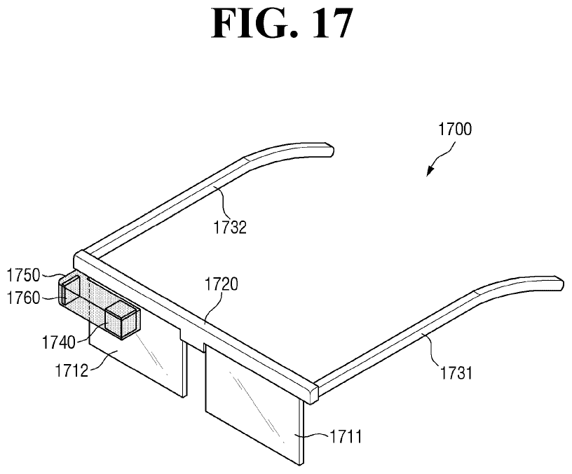

FIG. 17 is an illustrative view illustrating a virtual reality device including the display device 10 according to an embodiment.

A virtual reality device 1700 to which a display device 1760 according to an embodiment is applied is illustrated in FIG. 17. Here, the display device 1760 may be, for example, a display device 1760 including the components of FIGS. 1 to 16 described above. For example, the display device 1760 may be the display device 10 according to an embodiment.

Referring to FIG. 17, the virtual reality device 1700 according to an embodiment may be AR glasses in the form of glasses. The virtual reality device 1700 according to an embodiment may include the display device 1760, a left eye lens 1711, a right eye lens 1712, a support frame 1720, eyeglass frame legs 1731 and 1732, a reflective member 1740, and an accommodating portion 1750.

In FIG. 17, the virtual reality device 1700 in the form of AR glass is illustrated, but the virtual reality device 1700 according to an embodiment may also be applied to an HMD. In other words, the virtual reality device 1700 according to an embodiment is not limited to that illustrated in FIG. 17, and may be applied in various forms in various other mobile electronic devices.

The accommodating portion 1750 may include the display device 1760 and the reflective member 1740. An image displayed on the display device 1760 may be reflected by the reflective member 1740 and provided to a user's right eye through the right eye lens 1712. Accordingly, the user may view a virtual reality image displayed on the display device 1760 through the right eye.

It is illustrated in FIG. 17 that the accommodating portion 1750 is disposed at a right distal end of the support frame 1720, but an embodiment of the present disclosure is not limited thereto. For example, the accommodating portion 1750 may be disposed at a left distal end of the support frame 1720. In this case, an image displayed on the display device 1760 may be reflected by the reflective member 1740 and provided to a user's left eye through the left eye lens 1711. Accordingly, the user may view a virtual reality image displayed on the display device 1760 through the left eye. Alternatively, two of the accommodating portions 1750 may be disposed at both the left and right distal ends of the support frame 1720. In this case, the user may view a virtual reality image displayed on the display device 1760 through both the left and right eyes.

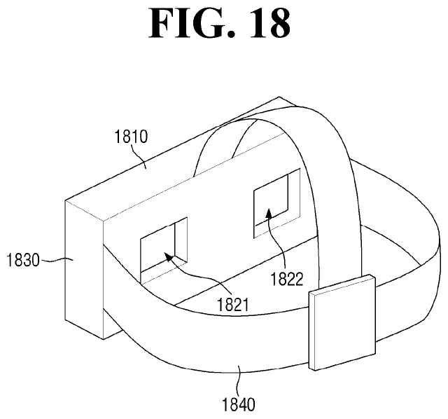

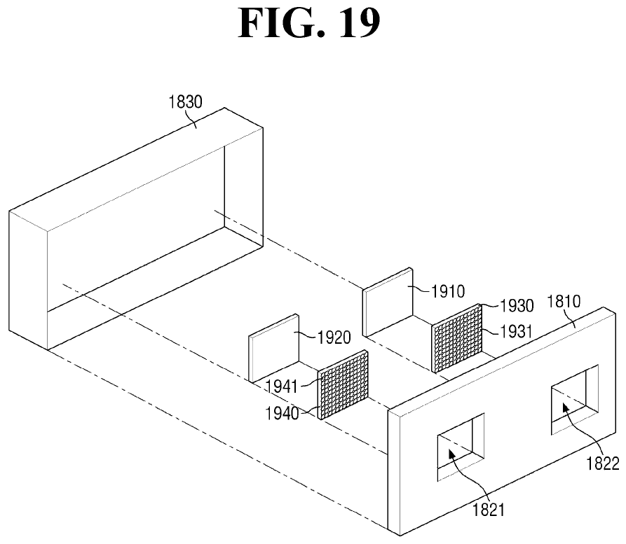

FIGS. 18 and 19 are views illustrating an HMD device to which the display device 10 according to an embodiment is applied.

Referring to FIGS. 18 and 19, the display device 10 according to an embodiment may be applied to an HMD device. The HMD device includes a first display device 1910 and a second display device 1920, each of which may be the display device 10 according to an embodiment. The first display device 1910 provides an image to the user's right eye, and the second display device 1920 provides an image to the user's left eye.

A first lens array 1930 may be disposed between the first display device 1910 and an accommodating portion cover 1810. The first lens array 1930 may include a plurality of lenses 1931. The plurality of lenses 1931 may be formed as convex lenses that are convex in a direction of the accommodating portion cover 1810.

A second lens array 1940 may be disposed between the second display device 1920 and the accommodating portion cover 1810. The second lens array 1940 may include a plurality of lenses 1941. The plurality of lenses 1941 may be formed as convex lenses that are convex in a direction of the accommodating portion cover 1810.

An accommodating portion 1830 accommodates the first display device 1910, the second display device 1920, the first lens array 1930, and the second lens array 1940. To accommodate the first display device 1910, the second display device 1920, the first lens array 1930, and the second lens array 1940, one surface of the accommodating portion 1830 may be opened.

The accommodating portion cover 1810 is disposed to cover the opened surface of the accommodating portion 1830. The accommodating portion cover 1810 may include a first opening 1821 where the user's left eye is disposed and a second opening 1822 where the user's right eye is disposed. It is illustrated in FIGS. 18 and 19 that the first opening 1821 and the second opening 1822 are formed in a quadrangular shape, but the present disclosure is not limited thereto. The first opening 1821 and the second opening 1822 may be formed in a circular shape or an elliptical shape. Alternatively, the first opening 1821 and the second opening 1822 may be combined to form one opening.

The first opening 1821 may be aligned with the second display device 1920 and the second lens array 1940, and the second opening 1822 may be aligned with the first display device 1910 and the first lens array 1930. Therefore, the user may view the image of the first display device 1910 magnified as a virtual image by the first lens array 1930 through the second opening 1822, and may view the image of the second display device 1920 magnified as a virtual image by the second lens array 1940 through the first opening 1821.

A head mounting band 1840 serves to fix the accommodating portion 1830 to a user's head so that the first opening 1821 and the second opening 1822 of the accommodating portion cover 1810 are disposed on the user's left and right eyes, respectively. The head mounting band 1840 may be connected to upper, left side, and right side surfaces of the accommodating portion 1830.

In concluding the detailed description, those skilled in the art will appreciate that many variations and modifications can be made to the disclosed embodiments without substantially departing from the principles of the present disclosure. Therefore, the disclosed embodiments are not for purposes of limitation.

What is claimed is:

1. A display device comprising:
a display panel,
wherein the display panel includes:
a semiconductor wafer substrate;
a complementary metal oxide semiconductor (CMOS) layer disposed on a first side of the semiconductor wafer substrate and including a plurality of display driving circuits that are driven independently of each other;
a transistor layer disposed on a second side of the semiconductor wafer substrate and including a plurality of pixel driving circuits connected to the plurality of display driving circuits through a contact hole in the semiconductor wafer substrate;
a light emitting element layer disposed on the second side of the semiconductor wafer substrate and including a light emitting element driven by the plurality of pixel driving circuits; and
an encapsulation layer disposed on the second side of the semiconductor wafer substrate.

2. The display device of claim 1, wherein the display panel includes a display area in which a plurality of pixels including the light emitting element are disposed, and a non-display area, and
the plurality of display driving circuits overlap the plurality of pixels in the display area.

3. The display device of claim 2, wherein the plurality of display driving circuits are disposed at intervals in the CMOS layer.

4. The display device of claim 2, wherein the plurality of display driving circuits include the same circuits.

5. The display device of claim 4, wherein the plurality of display driving circuits include:
a first display driving circuit disposed to correspond to a first area of the display area and including a first circuit for driving the plurality of pixel driving circuits; and
a second display driving circuit disposed to correspond to a second area of the display area and including a second circuit for driving the plurality of pixel driving circuits, and
the first circuit and the second circuit are the same.

6. The display device of claim 5, wherein the plurality of display driving circuits further include:
a third display driving circuit disposed to correspond to a third area of the display area and including a third circuit for driving the plurality of pixel driving circuits; and
a fourth display driving circuit disposed to correspond to a fourth area of the display area and including a fourth circuit for driving the plurality of pixel driving circuits, and
the first, second, third and fourth circuits are the same.

7. The display device of claim 6, wherein the contact hole includes:
a plurality of first contact holes connecting the first display driving circuit and the plurality of pixel driving circuits;
a plurality of second contact holes connecting the second display driving circuit and the plurality of pixel driving circuits;
a plurality of third contact holes connecting the third display driving circuit and the plurality of pixel driving circuits; and
a plurality of fourth contact holes connecting the fourth display driving circuit and the plurality of pixel driving circuits.

8. The display device of claim 1, wherein each of the plurality of pixel driving circuits includes an oxide-based thin film transistor.

9. The display device of claim 1, wherein the display panel further includes:
a color filter layer disposed on the second side of the semiconductor wafer substrate and including a color filter; and
a light control layer disposed on the second side of the semiconductor wafer substrate and including a refractive film.

10. The display device of claim 9, wherein the display panel further includes:
a first cover window disposed on the first side of the semiconductor wafer substrate; and
a second cover window disposed on the second side of the semiconductor wafer substrate.

11. A method for manufacturing a display device, the method comprising:
preparing a semiconductor wafer substrate;
forming a complementary metal oxide semiconductor (CMOS) layer including a plurality of display driving circuits that are driven independently of each other on a front surface of the semiconductor wafer substrate;
attaching a first cover window to the CMOS layer;
performing a chemical mechanical polishing pad (CMP) process step of polishing a rear surface of the semiconductor wafer substrate to expose contact holes connected to the plurality of display driving circuits;
forming a transistor layer including a plurality of pixel driving circuits connected to the plurality of display driving circuits through the contact holes on the rear surface of the semiconductor wafer substrate;
forming a light emitting element layer including a light emitting element driven by the plurality of pixel driving circuits on the transistor layer; and
forming an encapsulation layer on the light emitting element layer.

12. The method of claim 11, wherein a display panel included in the display device includes a display area in which a plurality of pixels including the light emitting element are disposed, and a non-display area, and
the plurality of display driving circuits overlap the plurality of pixels in the display area.

13. The method of claim 12, wherein the plurality of display driving circuits are disposed at intervals in the CMOS layer.

14. The method of claim 12, wherein the plurality of display driving circuits include the same circuits.

15. The method of claim 14, wherein the plurality of display driving circuits include:
a first display driving circuit disposed to correspond to a first area of the display area and including a first circuit for driving the plurality of pixel driving circuits; and
a second display driving circuit disposed to correspond to a second area of the display area and including a second circuit for driving the plurality of pixel driving circuits, and
the first circuit and the second circuit are the same.

16. The method of claim 15, wherein the plurality of display driving circuits further include:
a third display driving circuit disposed to correspond to a third area of the display area and including a third circuit for driving the plurality of pixel driving circuits; and
a fourth display driving circuit disposed to correspond to a fourth area of the display area and including a fourth circuit for driving the plurality of pixel driving circuits, and
the first, second, third and fourth circuits are the same.

17. The method of claim 16, wherein the contact hole includes:
a plurality of first contact holes connecting the first display driving circuit and the plurality of pixel driving circuits;
a plurality of second contact holes connecting the second display driving circuit and the plurality of pixel driving circuits;
a plurality of third contact holes connecting the third display driving circuit and the plurality of pixel driving circuits; and
a plurality of fourth contact holes connecting the fourth display driving circuit and the plurality of pixel driving circuits.

18. The method of claim 11, wherein each of the plurality of pixel driving circuits includes an oxide-based thin film transistor.

19. The method of claim 11, further comprising:
forming a color filter layer including a color filter on the encapsulation layer; and
forming a light control layer including a refractive film on the color filter layer.

20. The method of claim 19, further comprising attaching a second cover window to the light control layer.
